(19) United States
(12) Patent Application Publication
(10) Pub. No.: US 2024/0096014 A1
(43) Pub. Date: Mar. 21, 2024

(54) METHOD AND SYSTEM FOR CREATING AND SIMULATING A REALISTIC 3D VIRTUAL WORLD

(71) Applicant: Cognata Ltd., Rehovot (IL)

(72) Inventors: Dan ATSMON, Rehovot (IL); Guy TSAFRIR, Zikhron-Yaakov (IL); Eran ASA, Petach-Tikva (IL)

(73) Assignee: Cognata Ltd., Rehovot (IL)

(21) Appl. No.: 18/518,654

(22) Filed: Nov. 24, 2023

Related U.S. Application Data
(63) Continuation of application No. 15/990,877, filed on May 29, 2018, now abandoned.
Application No. 15/990,877 is a continuation-in-part of application No. PCT/IL2017/050598, filed on May 29, 2017.
(60) Provisional application No. 62/384,733, filed on Sep. 8, 2016.
(60) Provisional application No. 62/355,368, filed on Jun. 28, 2016.
(60) Provisional application No. 62/537,562, filed on Jul. 27, 2017.

(51) Int. Cl. G06T 17/05; G06T 19/00; G09B 9/04; G09B 9/048

(52) U.S. Cl. CPC G06T 17/05; G06T 19/003; G09B 9/04; G09B 9/048; G06N 20/10

(57) ABSTRACT

A computer implemented method of creating data for a host vehicle simulation, comprising: in each of a plurality of iterations of a host vehicle simulation using at least one processor for: obtaining from an environment simulation engine a semantic-data dataset representing a plurality of scene objects in a geographical area, each one of the plurality of scene objects comprises at least object location coordinates and a plurality of values of semantically described parameters; creating a 3D visual realistic scene emulating the geographical area according to the dataset; applying at least one noise pattern associated with at least one sensor of a vehicle simulated by the host vehicle simulation engine on the virtual 3D visual realistic scene to create sensory ranging data simulation of the geographical area; converting the sensory ranging data simulation to an enhanced dataset emulating the geographical area, the enhanced dataset comprises a plurality of enhanced scene objects.

### RELATED APPLICATIONS

This application is a continuation of U.S. patent application Ser. No. 15/990,877 filed on May 29, 2018, which is a Continuation-in-Part (CIP) of PCT Patent Application No. PCT/IL2017/050598 having International Filing Date of May 29, 2017, which claims the benefit of priority under 35 USC § 119(e) of U.S. Provisional Patent Application Nos. 62/384,733 filed on Sep. 8, 2016 and 62/355,368 filed on Jun. 28, 2016.

This application also claims the benefit of priority under 35 USC § 119(e) of U.S. Provisional Patent Application No. 62/537,562 filed on Jul. 27, 2017.

The contents of the above applications are all incorporated by reference as if fully set forth herein in their entirety.

### FIELD AND BACKGROUND OF THE INVENTION

The present invention, in some embodiments thereof, relates to creating a simulated model of a geographical area, and, more specifically, but not exclusively, to creating a simulated model of a geographical area, optionally including transportation traffic to generate simulation sensory data for training an autonomous driving system.

The arena of autonomous vehicles, either ground vehicles, aerial vehicles and/or naval vehicles has witnessed an enormous evolution during recent times. Major resources are invested in the autonomous vehicles technologies and the field is therefore quickly moving forward towards the goal of deploying autonomous vehicles for a plurality of applications, for example, transportation, industrial, military uses and/or the like.

The autonomous vehicles involve a plurality of disciplines targeting a plurality of challenges rising in the development of the autonomous vehicles. However, in addition to the design and development of the autonomous vehicles, there is a need for multiple and diversified support eco-systems for training, evaluating and/or validating the autonomous driving systems controlling the autonomous vehicles.

### SUMMARY OF THE INVENTION

It is an object of the present invention to provide a system and a method for creating a simulated model of a geographical area, and, more specifically, but not exclusively, to creating a simulated model of a geographical area, optionally including transportation traffic to generate simulation sensory data for training an autonomous driving system.

The foregoing and other objects are achieved by the features of the independent claims. Further implementation forms are apparent from the dependent claims, the description and the figures.

According to a first aspect of the invention, a computer implemented method of creating data for a host vehicle simulation comprises: in each of a plurality of iterations of a host vehicle simulation engine, using at least one processor for: obtaining from an environment simulation engine a semantic-data dataset representing a plurality of scene objects in a geographical area, each one of the plurality of scene objects comprises at least object location coordinates and a plurality of values of semantically described parameters; creating a virtual three dimensional (3D) visual realistic scene emulating the geographical area according to the semantic-data dataset; applying at least one noise pattern associated with at least one sensor of a vehicle simulated by the host vehicle simulation engine on the virtual 3D visual realistic scene to create sensory ranging data simulation of the geographical area; converting the sensory ranging data simulation to an enhanced semantic-data dataset emulating the geographical area, the enhanced semantic-data dataset comprises a plurality of enhanced scene objects comprising adjusted object location coordinates and a plurality of adapted values of respective semantically described parameters; and providing the enhanced semantic-data dataset to the host vehicle simulation engine for updating a simulation of the vehicle in the geographical area.

According to a second aspect of the invention, a system for creating data for a host vehicle simulation comprises: an input interface for obtaining from an environment simulation engine in each of a plurality of iterations a semantic-data dataset representing a plurality of scene objects in a geographical area, each one of the plurality of scene objects comprises at least object location coordinates and a plurality of values of semantically described parameters; at least one processor for: creating a virtual three dimensional (3D) visual realistic scene emulating the geographical area according to the semantic-data dataset; applying at least one noise pattern associated with at least one sensor of a vehicle simulated by a host vehicle simulation engine on the virtual 3D visual realistic scene to create sensory ranging data simulation of the geographical area; converting the sensory ranging data simulation to an enhanced semantic-data dataset emulating the geographical area, the enhanced semantic-data dataset comprises a plurality of enhanced scene objects comprising adjusted object location coordinates and a plurality of adapted values of respective semantically described parameters; and an output interface for providing the enhanced semantic-data dataset to the host vehicle simulation engine for updating a simulation of the vehicle in said geographical area.

With reference to the first and second aspects, in a first possible implementation of the first and second aspects of the present invention, creating the virtual 3D visual realistic scene comprises executing a neural network. The neural network receives the semantic-data dataset and generates the virtual 3D visual realistic scene according to the semantic-data dataset. Optionally, the neural network is trained using a perceptual loss function. Using a perceptual loss function, as opposed to a pixel level loss function, may reduce unrealistic differences between an input virtual 3D scene and a generated realistic virtual 3D scene and increase realism of the generated realistic 3D virtual scene, and thus may facilitate improved accuracy of an autonomous driving system using the generated realistic virtual 3D scene, according to one or more accuracy metrics. Optionally, the neural network is a generator network of a Generative Adversarial Neural Network (GAN) or of a Conditional Generative Adversarial Neural Network (cGAN). Optionally, the neural network is trained using optical flow estimation to reduce temporal inconsistency between consecutive frames of a created virtual 3D visual realistic scene.

With reference to the first and second aspects, in a second possible implementation of the first and second aspects of the present invention, the at least one sensor of the vehicle simulated by the host vehicle simulation engine is selected from a group of sensors consisting of: a camera, a video camera, an infrared camera, a night vision sensor, a Light Detection and Ranging (LIDAR) sensor, a radar, and an ultra-sonic sensor.

With reference to the first and second aspects, in a third possible implementation of the first and second aspects of the present invention, the output interface is at least one digital communication network interface and providing the enhanced semantic-data dataset to the host vehicle simulation engine comprises sending a stream of data to at least one other processor via the least one digital communication network interface connected to the at least one processor. Using a digital communication network interface allows generating the realistic 3D virtual scene at a location remote to a location where the host vehicle simulator is executed.

With reference to the first and second aspects, in a fourth possible implementation of the first and second aspects of the present invention, the system further comprises a digital memory for at least one of storing code and storing an enhanced semantic-data dataset. Optionally the digital memory is shared access by the host vehicle simulation engine. Providing the enhanced semantic-data dataset to the host vehicle simulation engine comprises storing a file on the shared access memory accessible by the host vehicle simulation engine. Using shared access memory may facilitate reducing latency in providing the enhanced semantic-data dataset, for example compared to using inter-process communications or a digital network, and thus improve performance of the host vehicle simulation engine, for example by increasing an amount of simulation iterations per an amount of time.

With reference to the first and second aspects, in a fifth possible implementation of the first and second aspects of the present invention, the system further comprises a digital data storage connected to the at least one processor via the output interface. Optionally, the digital data storage is selected from a group consisting of: a storage area network, a network attached storage, a hard disk drive, an optical disk, and a solid state storage. Providing the enhanced semantic-data dataset to the host vehicle simulation engine comprises storing a file on a digital data storage. Using a digital storage may facilitate asynchronous communication between the system and the host vehicle simulation engine.

With reference to the first and second aspects, in a sixth possible implementation of the first and second aspects of the present invention, the system further comprises using the at least one processor for generating report data comprising at least one of analysis report data and analytics report data; and outputting the report data.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic illustration of a system for enhancing a semantic-data dataset which is received from an environment simulation engine 201 for a host vehicle simulation engine and providing the semantic-data dataset to the host vehicle simulation engine, according to some embodiments of the present invention, for instance by implementing the method depicted in FIG. 2 and optionally described above;

FIG. 2 is a flowchart of an exemplary process of creating a stream of data for a host vehicle simulation engine, according to some embodiments of the present invention;

FIG. 3 depicts an exemplary flow of operations for generating a sensory ranging data simulation, according to some embodiments of the present invention;

FIGS. 4 and 5 graphically depict the creating of target lists that semantically represent parameters of objects of a scene in a geographical area, according to some embodiments of the present invention;

FIG. 6 is an exemplary flow of data, according to some embodiments of the present invention;

FIG. 7 graphically depicts how enhanced semantic data, that contains target lists as created according to FIGS. 4 and 5, is created by the system (right side of the line) and how this enhanced semantic data is forwarded to update sensor state and readings, according to some embodiments of the present invention; and

FIG. 8 graphically depicts how the system (right side of the line) updates a simulation executed externally, for example by a host vehicle simulation engine, according to some embodiments of the present invention.

### DESCRIPTION OF SPECIFIC EMBODIMENTS OF THE INVENTION

The present invention, in some embodiments thereof, relates to generating a stream of semantic data for an autonomous simulator, and, more specifically, but not exclusively, to enhancing semantic data representing objects in a geographical area by using simulation of ranging sensor noise patterns, according to some embodiments of the present invention.

Ranging sensors include sensors that require no physical contact with an object being detected. They allow identification of an object without actually having to come into contact with the obstacle. For example, in robotics, a ranging sensor allows a robot to identify an obstacle without having to come into contact with the obstacle. Some examples of ranging sensors are sonic scanning sensors (also known as SONAR), using sound waves, and light based sensors, using projected light waves. An example of a light based sensor is a Light Detection and Ranging (LIDAR) sensor, using a laser light that is swept across the Lidar sensor's field of view and analyzing reflection of the laser light.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device.

The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing.

A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network.

The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages.

The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

The flowchart and block diagrams in the figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s).

In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Various autonomous driving simulators have been developed during the last years. Such a simulator, which is also referred to as a host vehicle simulation engine, models or executes an autonomous driving system for example vehicle dynamics and low-level tracking controllers. In terms of the host vehicle dynamics, see for example W. Milliken and D. L. Milliken, Race car vehicle dynamics. Society of Automotive Engineers Warrendale, 1995, vol. 400. Many simulators used an overly simplified vehicle model.

Lower-level vehicle controllers (e.g., path tracking and speed regulation) are external to a motion planner. In use, as the host vehicle moves, segments of a model mapping proximity to the vehicle are loaded from an environment simulation engine that models different invariant of a geographic area (e.g., road network, curb, etc.) usually including varying world elements (e.g., general static or moving objects).

The environment simulation engine provides ground-truth data. For instance, the environment simulation engine may include a road network that provides interconnectivity of roads and roads' lane-level information that specifies the drivable regions. The environment simulation engine makes use of road segments, where each segment may contain one or more parallel lanes.

Each lane may be specified by a series of global way-points. Connectivity among lanes is defined by pairs of exit/entry way-points. Alternatively for each waypoint, lane width (w) and speed limit (vlim) are added to global position (x and y). Station coordinate(s) may be calculated for each waypoint by calculating piecewise-linear cumulative distance along-road. Permanent obstacles may be represented in the environment simulation engine as stationary environment constraints that make certain regions non-traversable, such as curb and lane fences.

Unlike general objects described below, permanent obstacles typically do not have a separable shape. In use, as a host vehicle is simulated as moving, segments of model mapping proximity to the vehicle are loaded from the environment simulation engine to the host vehicle simulation engine. Furthermore, the environment simulation engine may simulate general objects such as dynamic objects. Various static and moving objects are modeled in the urban environment, for example objects of different types with different motion dynamics.

The trivial nonmovement model is for static objects (e.g., trash bins), which only contains unchanging pose information; a particle movement model may be used for objects whose motion can be omnidirectional (e.g., pedestrians). A kinematic bicycle model may be used to model objects with non-holonomic kinematic constraints (e.g., bicyclists and other passenger vehicles), hence there is a need for a separate perception simulation module to mimic realistic perception outcomes.

In order to facilitate fast and efficient computation of the driving simulation, the different invariant of the geographic area including the varying world elements are encoded by the environment simulation engine as a semantic-data dataset. For example, in each simulation iteration, a plurality of scene objects are forwarded by the environment simulation engine to be loaded to the host vehicle simulation engine. As used herein, a simulation iteration is an event such as loading or storing data representing a change in a scene which surrounds a host vehicle simulated by the host vehicle simulation engine. The loading may be done upon demand and/or iteratively every time frame and/or based on simulated velocity change of the vehicle simulated by the host vehicle simulation engine.

The present invention, according to some embodiments thereof, allows enhancing a semantic-data dataset outputted by the environment simulation engine, for instance by adapting the semantic-data dataset to emulate the geographic area as captured by actual sensors, for example ranging sensors, of the simulated vehicle. The sensor(s) include a LIDAR sensor, radar, an ultra-sonic sensor, a camera, an infrared camera and/or the like. In use, a semantic-data dataset received from an environment simulation engine is received and processed to be enhanced, for instance using one or more servers with one or more processors and/or designated processing hardware. The enhancement is optionally done as described below, for instance using the models described in international application number PCT/IL2017/050598 filed on May 29, 2017 which is incorporated herein by reference. In each iteration, a semantic-data dataset is received from the simulation engine and enhanced to provide an enhanced semantic-data dataset to the host vehicle simulation engine, for instance as a stream of data and/or a file stored in a shared access memory. Using the enhanced semantic-data dataset in the host vehicle simulation engine may improve performance of a host vehicle simulation engine, for example by reducing time required to train an autonomous driving system executed by the host vehicle simulation engine and/or by improving the autonomous driving system's accuracy according to one or more accuracy metrics, for example amount of collisions with one or more obstacles, compared to training the autonomous driving system using the semantic-data dataset as received from the environment simulation engine.

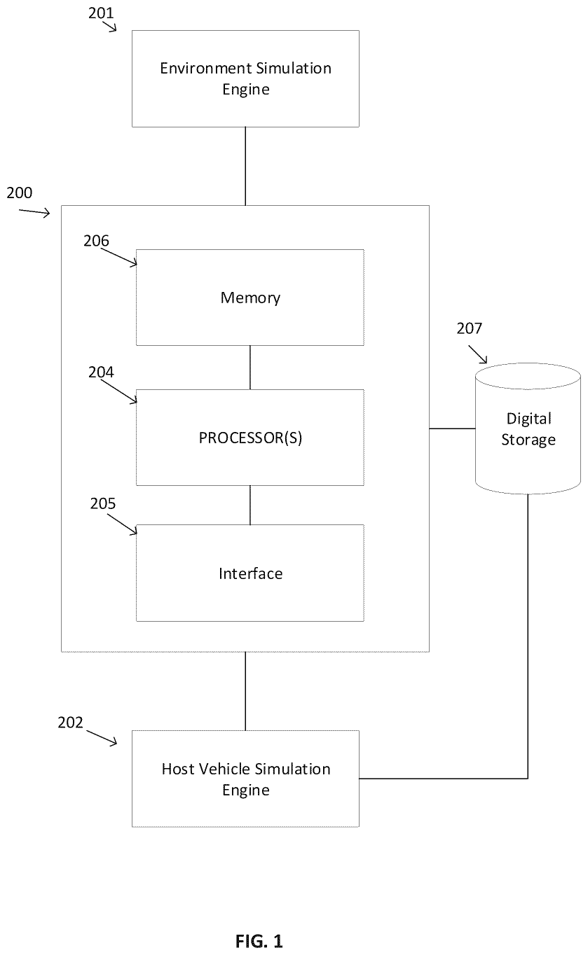

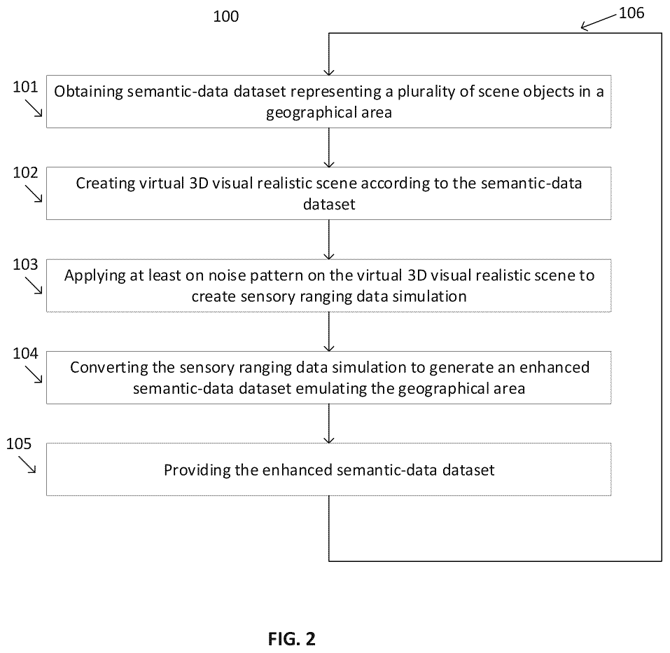

Referring now also to the drawings. FIG. 1 is a schematic illustration of a system 200 for enhancing semantic-data dataset which is received from an environment simulation engine 201 for a host vehicle simulation engine 202, and providing the semantic-data dataset to the host vehicle simulation engine 202, according to some embodiments of the present invention, for instance by implementing the method depicted in FIG. 2 and optionally described above. Optionally, system 200 comprises at least one processor 204 used for enhancing the semantic-data dataset. Optionally, the at least one processor 204 is connected to at least one interface 205 for the purpose of receiving the semantic-data dataset from the environment simulation engine 201, and additionally or alternately for providing the enhanced semantic-data data set to the host vehicle simulation engine 202. Optionally, at least one interface 205 is a digital communication network interface. Optionally, the at least one digital communication network interface 205 is connected to a Local Area Network (LAN), for example an Ethernet LAN or a wireless LAN. Optionally, the at least one digital communication network interface 205 is connected to a Wide Area Network (WAN), for example the Internet.

Optionally, system 200 comprises at least one digital data storage 207, for the purpose of providing the enhanced semantic-data dataset to the host vehicle simulation engine 202, such that at least one digital data storage 207 is accessible by the host vehicle simulation engine 202. Optionally the at least one digital storage 207 is electrically connected to at least one processor 204, for example when at least one digital storage 207 a hard disk drive or a solid state storage. Optionally, the at least one digital storage 207 is connected to at least one processor 204 via at least one digital communication network interface 205, for example when at least one digital storage 207 is a storage area network or a network attached storage.

Optionally the least one interface 205 is a digital memory interface, electrically connecting at least one processor 204 to at least one digital memory 206. Optionally, at least one digital memory 206 stores simulation enhancing code executed by at least one processor 204. Additionally or alternately, at least one digital memory is additionally accessed by the host vehicle simulation engine 202 and at least one processor 204 stores the enhanced semantic-data dataset on at least one digital memory 206 for the purpose of providing to the host vehicle simulation engine 202.

Reference is now made also to FIG. 2. FIG. 2 is a flowchart of an exemplary process 100 of creating a stream of data for a host vehicle simulation engine, according to some embodiments of the present invention. As shown at 106, the process is optionally iterative so that 101-105 are repeated in each of a plurality of simulation iterations for providing real time information to a host vehicle simulation engine, for instance as described above.

The process 100 may be implemented using a system adapted to enhance semantic data for training an autonomous driving system controlling a vehicle, for example, a ground vehicle, an aerial vehicle and/or a naval vehicle in a certain geographical area using a simulated virtual realistic model replicating the certain geographical area, for example system 200 above.

When implemented by the system 200, 101-105 are optionally performed iteratively by one or more processors 204 of the system 200 that executes a simulation enhancing code stored in a memory 206. First, as shown at 101, semantic data dataset representing a plurality of scene objects in a geographical area is obtained via at least one interface 205, for instance from a code executed with the environment simulation engine 201. The data may be received in a message and/or accessed when stored in a memory.

The scene objects are different invariants of a geographic area, optionally including varying world elements, for instance as described above. The geographical area is optionally the segments of occupancy grids maps in proximity to the vehicle, for instance segments that model different invariants of a geographic area including varying world elements.

Each one of the scene objects comprising object location coordinates and a plurality of values of semantically described parameters. The values may be indicative of color, size, shape, text on signboards, states of traffic lights, velocity, movement parameters, behaviour parameters and/or the like.

Now, as shown at 102, a virtual 3D visual realistic scene emulating the geographical area is generated (created) according to the received semantic-data dataset. The generation is optionally performed by placing the objects in a virtual three dimensional (3D) visual realistic scene emulating the geographical area, for instance the different invariant of the geographic area, optionally including varying world elements such as vehicles and pedestrians.

The virtual 3D visual realistic scene may be based on segments of data of a synthetic 3D imaging data generated from a virtual realistic model created by obtaining visual imagery data of the geographical area, for example, one or more two dimensional (2D) and/or 3D images, panoramic image and/or the like captured at ground level, from the air and/or from a satellite. The visual imagery data may be obtained from, for example, Google Earth, Google Street View, OpenStreetCam, Bing maps and/or the like.

Optionally, one or more trained classifiers (classification functions) may be applied to the visual imagery data to identify different invariant of the geographic area, optionally including the varying world elements. The invariant of the geographic area and the varying world elements may be referred to herein as objects, such as static objects, for example, a road, a road infrastructure object, an intersection, a sidewalk, a building, a monument, a natural object, a terrain surface and/or the like and dynamic objects as vehicles and/or pedestrians. The classifier(s) may classify the identified static objects to class labels based on a training sample set adjusted for classifying objects of the same type as the target objects.

The identified labeled objects may be superimposed over the geographic map data obtained for the geographical, for example, a 2D map, a 3D map, an orthophoto map, an elevation map, a detailed map comprising object description for objects present in the geographical area and/or the like. The geographic map data may be obtained from, for example, Google maps, OpenStreetMap and/or the like.

A Generative Adversarial Neural Network (GAN) is a network having two neural networks, known as a generator (or refiner) and a discriminator, where the two neural networks are trained at the same time and compete again each other in a minimax game. A Conditional Generative Adversarial Neural Network (cGAN) is a GAN that uses extra conditional information Y that describes some aspect of the cGAN's data, for example attributes of the required generated object. Optionally, a GAN or cGAN's generator comprises a plurality of convolutional neural network layers, without fully connected and pooling neural network layers.

The labeled objects are overlaid over the geographic map(s) in the respective location, position, orientation, proportion and/or the like identified by analyzing the geographic map data and/or the visual imagery data to create a labeled model of the geographical area. Using one or more techniques, for example, a cGAN, stitching texture(s) (of the labeled objects) retrieved from the original visual imagery data, overlaying textured images selected from a repository (storage) according to the class label and/or the like the labeled objects in the labeled model may be synthesized with (visual) image pixel data to create the simulated virtual realistic model replicating the geographical area. Optionally, the one or more techniques comprise using one or more neural networks. Optionally, the one or more neural networks are a GAN or a cGAN. Optionally, the neural network one or more neural networks are the generator network of a GAN or a cGAN.

Temporal consistency refers to consistency with regards to one or more image attributes in a sequence of images. Examples of temporal inconsistency are flickering of an object between two consecutive frames, and a difference in color temperature or lighting level between two consecutive frames exceeding an identified threshold difference. Optical flow estimation refers to estimating a pattern of apparent motion of objects, surfaces, and edges in a visual scene caused by the relative motion between an observer and a scene. Optionally, the one or more neural networks are trained using optical flow estimation, to reduce temporal inconsistency between consecutive frames of a created virtual 3D visual realistic scene (model). Optionally, the one or more neural networks are trained using a perceptual loss function, based on one or more objects identified in images of the virtual model, as opposed to a pixel-wise difference between images of the virtual model. Optionally, the one or more objects are identified in the images using a convolutional neural network feature extractor.

Optionally, the virtual realistic model is adjusted according to one or more lighting and/or environmental (e.g. weather, timing etc.) conditions to emulate various real world environmental conditions and/or scenarios, in particular, environmental conditions typical to the certain geographical area.

The synthetic 3D imaging data may be created as described in international application number PCT/IL2017/050598 filed on May 29, 2017 which is incorporated herein by reference. For example, the synthetic 3D imaging data may be generated to depict the virtual realistic model from a point of view of one or more emulated sensors mounted on an emulated vehicle moving in the virtual realistic model. The emulated sensor(s) may be a camera, a video camera, an infrared camera, a night vision sensor and/or the like which are mounted on a real world vehicle controlled by the autonomous driving system.

Moreover, the emulated imaging sensor(s) may be created, mounted and/or positioned on the emulated vehicle according to one or more mounting attributes of the imaging sensor(s) mounting on the real world vehicle, for example, positioning (e.g. location, orientation, elevations, etc.), field of view (FOV), range, overlap region with adjacent sensor(s) and/or the like. In some embodiments, one or more of the mounting attributes may be adjusted for the emulated imaging sensor(s) to improve perception and/or capture performance of the imaging sensor(s).

Based on analysis of the capture performance for alternate mounting options, one or more recommendation may be offered to the autonomous driving system for adjusting the mounting attribute(s) of the imaging sensor(s) mounting on the real world vehicle. The alternate mounting options may further suggest evaluating the capture performance of the imaging sensor(s) using another imaging sensor(s) model having different imaging attributes, i.e. resolution, FOV, magnification and/or the like.

Optionally, the received semantic data does not include information about moving objects or kinematics thereof. In such embodiments one or more dynamic objects may be injected into the virtual realistic model, for example, a ground vehicle, an aerial vehicle, a naval vehicle, a pedestrian, an animal, vegetation and/or the like. The dynamic object(s) may further include dynamically changing road infrastructure objects, for example, a light changing traffic light, an opened/closed railroad gate and/or the like. Movement of one or more of the dynamic objects may be controlled according to movement patterns predefined and/or learned for the certain geographical area.

In particular, movement of one or more ground vehicles inserted into the virtual realistic model may be controlled according to driver behavior data received from a driver behavior simulator. The driver behavior data may be adjusted according to one or more driver behavior patterns and/or driver behavior classes exhibited by a plurality of drivers in the certain geographical area, i.e. driver behavior patterns and/or driver behavior classes that may be typical to the certain geographical area.

The driver behavior classes may be identified through big-data analysis and/or analytics over a large data set of sensory data, for example, sensory motion data, sensory ranging data and/or the like collected from a plurality of drivers moving in the geographical area.

The sensory data may include, for example, speed, acceleration, direction, orientation, elevation, space keeping, position in lane and/or the like. One or more machine learning algorithms, for example, a neural network (e.g. Deep learning Neural Network (DNN), Gaussian Mixture Model (GMM), etc.), an Support Vector Machin (SVM) and/or the like may be used to analyze the collected sensory data to detect movement patterns which may be indicative of one or more driver behavior patterns. The driver behavior pattern(s) may be typical to the geographical area and therefore, based on the detected driver behavior pattern(s), the drivers in the geographical area may be classified to one or more driver behavior classes representing driver prototypes. The driver behavior data may be further adjusted according to a density function calculated for the geographical area which represents the distribution of the driver prototypes in the simulated geographical area. Optionally, additional data relating to the emulated vehicle is simulated and injected to the autonomous driving system. The simulated additional data may include, for example, sensory motion data presenting motion information of emulated vehicle, transport data simulating communication of the emulated vehicle with one or more other entities over one or more communication links, for example, Vehicle to Anything (V2X) and/or the like.

Now, as shown at 103, one or more noise patterns associated with sensors and/or additional vehicle hardware (e.g. communication units, processing units, and/or the like) of the vehicle simulated by the host vehicle simulation engine are applied to the virtual 3D visual realistic scene to create a sensory ranging data simulation of the geographical area. Some examples of sensors are a camera, a video camera, an infrared camera, a night vision sensor, a LIDAR sensor, a radar and an ultra-sonic sensor.

The noise patterns may include noise effects induced by one or more of the objects detected in the specific geographical area or in a general geographical area. The noise pattern(s) may describe one or more noise characteristics, for example, noise, distortion, latency, calibration offset and/or the like. The noise patterns(s) may be identified through big-data analysis and/or analytics over a large data set comprising a plurality of real world range sensor(s) readings collected for the geographical area and/or for other geographical locations. The big-data analysis may be done using one or more machine learning algorithms, for example, a neural network such as, for instance, a Deep learning Neural Network (DNN), a Gaussian Mixture Model (GMM), etc., a Support Vector Machine (SVM) and/or the like.

Optionally, in order to more accurately simulate the geographical area, the noise pattern(s) may be adjusted according to one or more object attributes of the objects detected in the geographical area, for example, an external surface texture, an external surface composition, an external surface material and/or the like. The noise pattern(s) may also be adjusted according to one or more environmental characteristics, for example, weather, timing (e.g. time of day, date) and/or the like. In some embodiments, one or more mounting attributes may be adjusted for the emulated range sensor(s) to improve accuracy performance of the range sensor(s).

The sensory ranging data simulation is created to emulate one or more sensory data feeds, for example, imaging data, ranging data, motion data, transport data and/or the like which may be injected to the host vehicle simulation engine during a training session.

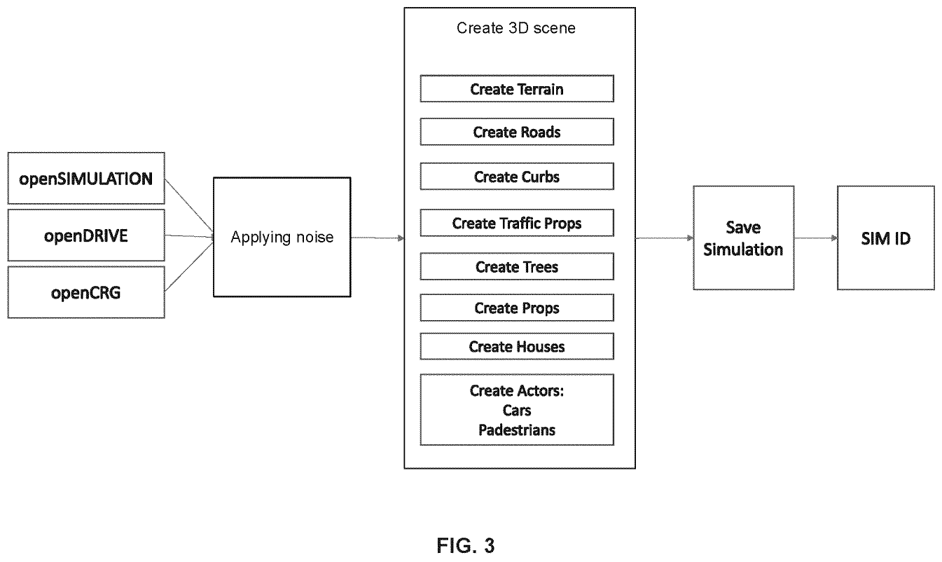

Reference is now made also to FIG. 3, which depicts an exemplary flow of operations for generating a sensory ranging data simulation. The sensory ranging data simulation includes emulation of terrain, roads, curbs, traffic properties, trees, props, houses and/or dynamic objects as outputted by actual sensors when the sensors are active in the geographic area, for example as described in international application number PCT/IL2017/050598 filed on May 29, 2017 which is incorporated herein by reference.

Reference is now made again to FIG. 2. As shown at 104, the sensory ranging data simulation is now converted to an enhanced semantic-data dataset emulating the geographical area. The enhanced semantic-data dataset comprises a plurality of enhanced scene objects having object location coordinates adjusted when the noise patterns have been applied and/or a plurality of values of respective semantically described parameters when the noise patterns have been applied. The enhanced semantic-data dataset comprises enhanced scene objects which are optionally similar to the received scene objects and comprises adjusted object location coordinates and/or adapted values of semantically described parameters of the geographical area.

As shown at 105, the enhanced semantic-data dataset is now outputted, for example injected to the host vehicle simulation engine, for instance using native interfaces and/or stored in a memory accessible to the host vehicle simulation engine. Additionally and/or alternatively, the enhanced semantic-data dataset may be injected using one or more virtual drivers using, for example, Application Programming Interface (API) functions of the autonomous driving system, a Software Development Kit (SDK) provided for the autonomous driving system and/or for the training system and/or the like. Optionally, the outputted enhanced semantic-data dataset is stored in at least one data storage 207. Optionally, at least one data storage 207 comprises a database.

Optionally, process 100 may further comprise generating report data and outputting the report data. The report data may comprise one or more of data analytics and data analysis. Data analysis refers to a historical view of a system's operation, for example when executing process 100. Data analytics refers to modeling and predicting future results of a system, for example when executing process 100. Optionally, generating the report data comprises applying big data analysis methods as known in the art.

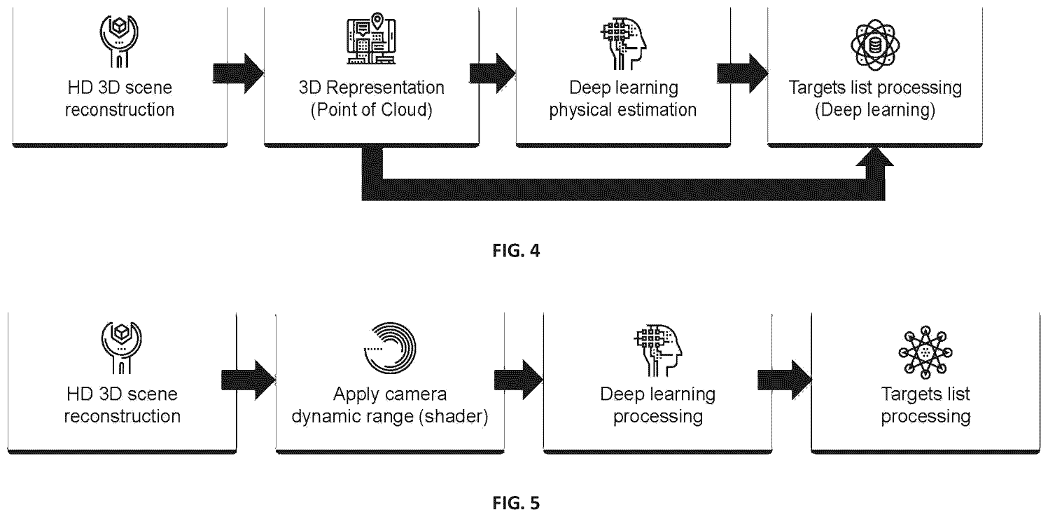

Reference is now made also to FIGS. 4 and 5. The enhanced semantic data optionally comprises target list(s) of objects; each includes values of parameters to emulate how the physical world is perceived by sensors of a vehicle hosting a simulated autonomous driving system. FIGS. 4 and 5 depict the creating of such target lists using deep neural network learning techniques, as known in the art.

The enhanced semantic-data dataset may be outputted as a stream of semantic information representing the geographical area to the host vehicle simulation engine.

The enhanced semantic-data dataset may be divided to a number of channels each representing a reading of different vehicle sensors which are emulated as described above.

Reference is now made again to FIG. 1. As indicated above and shown at 106, 101-105 are iteratively repeated, optionally for an identified amount of iterations.

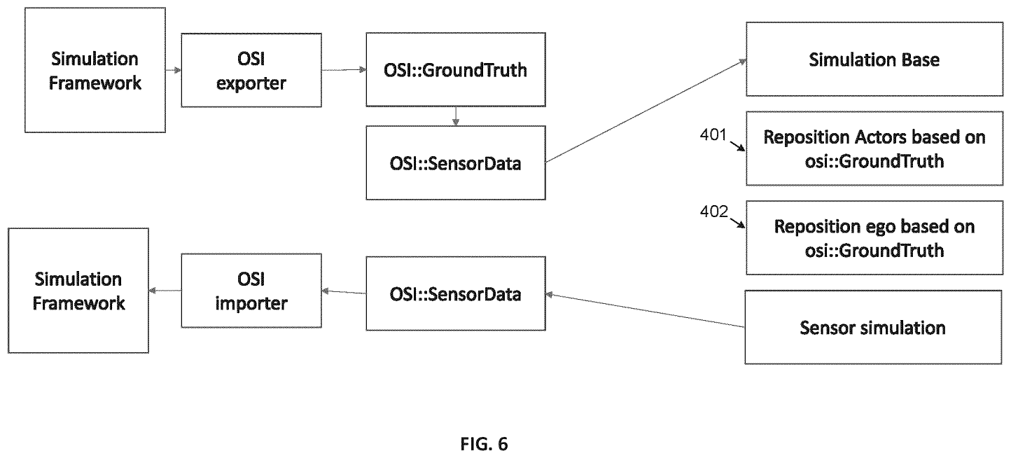

Reference is now made also to FIG. 6, showing an exemplary flow of data. The simulation framework is received from the environment simulation engine via an Open System Interconnection (OSI) exporter and received as ground truth, optionally together with sensor data as input for generating a simulation as described in 102 and 103 above. Optionally, dynamic objects such as actors are added to the simulation as shown at 401 and/or repositioned in the simulation as shown at 401. Optionally, ego-motion Estimation of one or more sensors (e.g. velocity and yaw rate (rotational speed around the height axis) is added to the simulation as shown at 402.

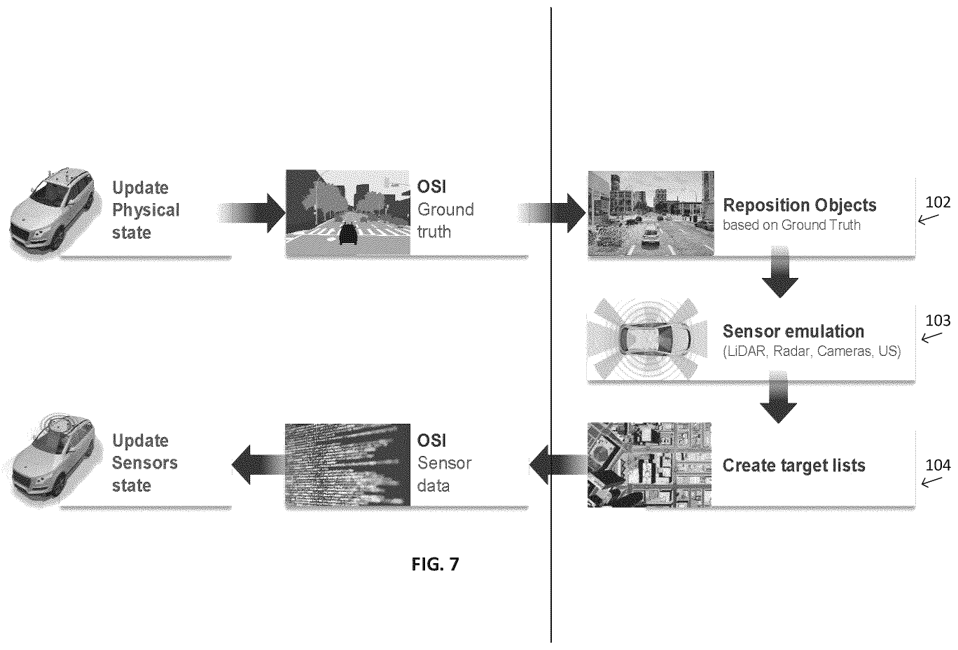

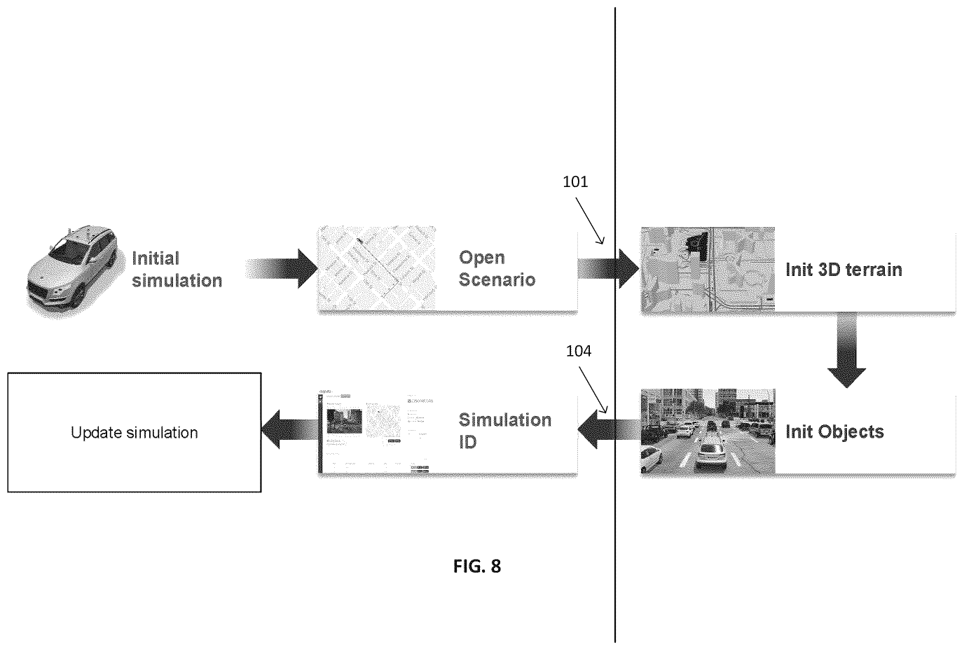

This allows calculating large rotational velocities around axes due to braking or bad roads (tilt and roll motion). The simulation is then converted to be inputted using OSI importer to the simulation framework of the host vehicle simulation engine, for example as described above. Reference is now made also to FIG. 7, graphically depicting how enhanced semantic data that contains target lists that semantically represents parameters of objects of a scene in a geographical area is created by the system (right side of the line) and how this enhanced semantic data is forward to update sensor state and readings. Optionally, the target lists are created as depicted in FIGS. 4 and 5. Reference is now also made to FIG. 8, graphically depicting how the system (right side of the line) updates a simulation executed externally, for example by a host vehicle simulation engine.

It is expected that during the life of a patent maturing from this application many relevant devices, systems, methods and computer programs will be developed and the scope of the terms imaging sensor, range sensor, machine learning algorithm and neural network are intended to include all such new technologies a priori.

As used herein the term “about” refers to ±10%.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

The word “exemplary” is used herein to mean “serving as an example, an instance or an illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A computer implemented method of creating data for a host vehicle simulation, comprising:
in each of a plurality of iterations of a host vehicle simulation engine, simulating a certain geographic area, using at least one processor for:
obtaining from an environment simulation engine a semantic-data dataset representing a plurality of scene objects present in said geographical area, each one of said plurality of scene objects is individually described within said semantic-data dataset, wherein a description of each of the plurality of objects comprises at least object location coordinates and a plurality of values of semantically described parameters, said semantically described parameters are indicative of at least one member of a group consisting of color, size, shape, text on signboards and states of traffic lights;
creating a virtual three dimensional (3D) visual realistic scene emulating said geographical area according to said semantic-data dataset, by placing individually, at least some of said objects in said virtual 3D visual realistic scene and by injecting one or more dynamic or moving objects into said virtual 3D visual realistic scene;
applying at least one noise pattern associated with at least one sensor of a vehicle simulated by said host vehicle simulation engine on said virtual 3D visual realistic scene to create sensory ranging data simulation of said geographical area;
converting said sensory ranging data simulation to an enhanced semantic-data dataset emulating said geographical area by enhancing said plurality of scene objects comprising:
adjusting object location coordinates based on said created sensory ranging data; and
adapting values of said semantically described parameters,
based on said created sensory ranging data; and
providing said enhanced semantic-data dataset to said host vehicle simulation engine for updating a simulation of said vehicle in said geographical area.

2. The method of claim 1, wherein creating said virtual 3D visual realistic scene comprises executing a neural network;
wherein said neural network receives said semantic-data dataset; and
wherein said neural network generates said virtual 3D visual realistic scene according to said semantic-data dataset.

3. The method of claim 2, wherein said neural network is trained using a perceptual loss function.

4. The method of claim 2, wherein said neural network is a generator network of a Generative Adversarial Neural Network (GAN) or of a Conditional Generative Adversarial Neural Network (cGAN).

5. The method of claim 1, wherein said at least one sensor of said vehicle simulated by said host vehicle simulation engine is selected from a group of sensors consisting of: a camera, a video camera, an infrared camera, a night vision sensor, a Light Detection and Ranging (LIDAR) sensor, a radar, and an ultra-sonic sensor.

6. The method of claim 1, wherein providing said enhanced semantic-data dataset to said host vehicle simulation engine comprises sending a stream of data to at least one other processor via at least one digital communication network interface connected to said at least one processor.

7. The method of claim 1, wherein providing said enhanced semantic-data dataset to said host vehicle simulation engine comprises storing a file on a shared access memory accessible by said host vehicle simulation engine.

8. The method of claim 1, wherein providing said enhanced semantic-data dataset to said host vehicle simulation engine comprises storing a file on a digital data storage.

9. The method of claim 2, wherein said neural network is trained using optical flow estimation to reduce temporal inconsistency between consecutive frames of a created virtual 3D visual realistic scene.

10. The method of claim 1, further comprising using the at least one processor for:
generating report data comprising at least one of analysis report data and analytics report data; and
outputting said report data.

11. The method of claim 1, wherein said semantically described parameters are further indicative of at least one member of a group consisting of velocity, movement parameters and behavior parameters.

12. The method of claim 1, wherein at least one of said one or more dynamic or moving objects is a ground vehicle;
wherein emulating movement of said ground vehicle is controlled according to driver behavior data received from a driver behavior simulator and adjusted according to one or more driver behavior patterns and/or driver behavior classes; and
wherein said one or more driver behavior patterns and said driver behavior classes are identified through big-data analysis over a large data set of sensory data collected from a plurality of drivers having driver behavior patterns and/or driver behavior classes typical to said geographical area.

13. The method of claim 1, wherein a time between consecutive iterations is determined based on one of a predefined time frame and a simulated velocity change of a vehicle simulated by said host vehicle simulation engine.

14. The method of claim 1, wherein said creating said virtual 3D visual realistic scene comprising overlaying visual imagery of said at least some of said objects, labeled with class labels, over a geographic map of said geographical area, each in a respective location, position, orientation and proportion identified by analyzing said geographic map.

15. The method of claim 12, wherein said sensory data of said large data set includes at least one of speed, acceleration, direction, orientation, elevation, space keeping and position in lane.

16. The method of claim 12, wherein said big-data analysis is conducted using one or more machine learning algorithms which are members of a group consisting of a neural network and a Support Vector Machine (SVM).

17. The method of claim 1, further comprising adjusting the at least one noise pattern according to at least one environmental characteristic, said at least one environmental characteristic is a member a group consisting of weather, time of day and date.

18. The method of claim 1, further comprising adjusting said enhanced semantic-data dataset emulating said geographical area based on mounting attributes of the at least one sensor.

19. A system for creating data for a host vehicle simulation, comprising:
an input interface for obtaining from an environment simulation engine in each of a plurality of iterations of a host vehicle simulation engine, simulating a certain geographic area, a semantic-data dataset representing a plurality of scene objects present in said geographical area, each one of said plurality of scene objects is individually described within said semantic-data dataset, wherein a description of each of the plurality of objects comprises at least object location coordinates and a plurality of values of semantically described parameters, said semantically described parameters are indicative of at least one member of a group consisting of color, size, shape, text on signboards and states of traffic lights;
at least one processor for conducting in each of said plurality of iterations:
creating a virtual three dimensional (3D) visual realistic scene emulating said geographical area according to said semantic-data dataset, by placing individually, at least some of said objects in said virtual 3D visual realistic scene and by injecting one or more dynamic or moving objects into said virtual 3D visual realistic scene;
applying at least one noise pattern associated with at least one sensor of a vehicle simulated by a host vehicle simulation engine on said virtual 3D visual realistic scene to create sensory ranging data simulation of said geographical area;
converting said sensory ranging data simulation to an enhanced semantic-data dataset emulating said geographical area by enhancing said plurality of scene objects comprising:
adjusting object location coordinates based on said created sensory ranging data; and
adapting values of said semantically described parameters, based on said created sensory ranging data; and
an output interface for providing said enhanced semantic-data dataset to said host vehicle simulation engine for updating a simulation of said vehicle in said geographical area.

20. The system of claim 19, wherein said output interface is a digital communication network interface.

21. The system of claim 19, further comprising a digital memory for at least one of storing code and storing an enhanced semantic-data dataset.

22. The system of claim 19, further comprising a digital data storage connected to said at least one processor via said output interface.

23. The system of claim 19, wherein said digital data storage is selected from a group consisting of: a storage area network, a network attached storage, a hard disk drive, an optical disk, and a solid-state storage.
